(19) United States
(12) Patent Application Publication
(10) Pub. No.: US 2005/0036380 A1
(43) Pub. Date: Feb. 17, 2005

(54) Method and system of adjusting DRAM refresh interval

(76) Inventor: Yuan-Mou Su, Tainan County (TW)

Correspondence Address: BIRCH STEWART KOLASCH & BIRCH, PO BOX 747, FALLS CHURCH, VA, 22040-0747, US

(21) Appl. No.: 10/640,313

(22) Filed: Aug. 14, 2003

(51) Int. Cl. G11C 7/00

(52) U.S. Cl. 365/222

(57) ABSTRACT

A method of refreshing a DRAM chip. A working temperature is detected for the DRAM, and a corresponding refresh interval is decided accordingly. A refresh timing clock is generated with the corresponding refresh interval, and the DRAM is refreshed. The refresh interval decreases with increased working temperature, and increased with working temperature decrease.

### BACKGROUND OF THE INVENTION

1. Field of the Invention

The present invention relates to a method and apparatus of adjusting the refresh interval of a DRAM (dynamic random access memory), and more particularly a method and apparatus which can generate different DRAM refresh intervals according to the environmental temperature.

2. Description of the Related Art

DRAM, dynamic random access memory, is known to have high integration density, low cost, and high read speed. Therefore it is widely applied to electronic products. However, in DRAM, electric charge represents data, and inside electric charge is lost with time. The main cause of the electric leakage is the reverse bias voltage leakage current of PN junction of the NMOS of the DRAM memory cell. Thus, DRAM must update internal memory data to avoid data loss after a period of time, a process referred to as refresh, with the period required referred to as refresh interval. In other words, when the DRAM is in standby mode, DRAM must consume a specific amount of energy to perform the refresh process.

Thus, power consumed increases if the refresh interval is shorter.

However, when DRAM is used in portable electronic products such as PDA, the battery-provided energy is limited. To extend using time, power must be expended as conservatively as possible, including that used by DRAM. From above mentioned, the power consumed must be devoted to be decreased.

Therefore, power consumption of a DRAM, especially in refresh function, has become an important issue in DRAM research.

### SUMMARY OF THE INVENTION

Accordingly, an object of the present invention is to provide a flexible refresh interval for DRAM refresh, to avoid unneeded or incomplete refresh operations, contributing to power expenditures.

In order to achieve the above object, the invention provides a method for adjusting DRAM refresh interval.

First, a working temperature is detected for the DRAM. Then, accordingly, a corresponding refresh interval is decided, according to a comparison table. Finally a refresh timing clock is generated with the corresponding refresh interval, and the refresh process for the DRAM is performed.

The present invention provides a DRAM refresh system, embedded in a DRAM chip and comprising a temperature sensor, which detects a working temperature for the DRAM, to generate a corresponding temperature signal, a clock generator generating a refresh timing clock with the corresponding refresh interval, and a refresh module according to the refresh timing clock to perform a refresh for the DRAM.

A detailed description is given in the following with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a block diagram in accordance with the present invention; and

FIG. 2 is a circuit diagram of a partial oscillator.

### DETAILED DESCRIPTION OF THE INVENTION

Reverse bias voltage leaking current raises commensurate with increased environmental temperature, causing increased memory charge electron loss, so the refresh interval of DRAM should decrease when the working temperature of IC raise.

Conversely, when working temperature of the IC decreases, the refresh interval increases to conserve power used by refresh, increasing energy efficiency.

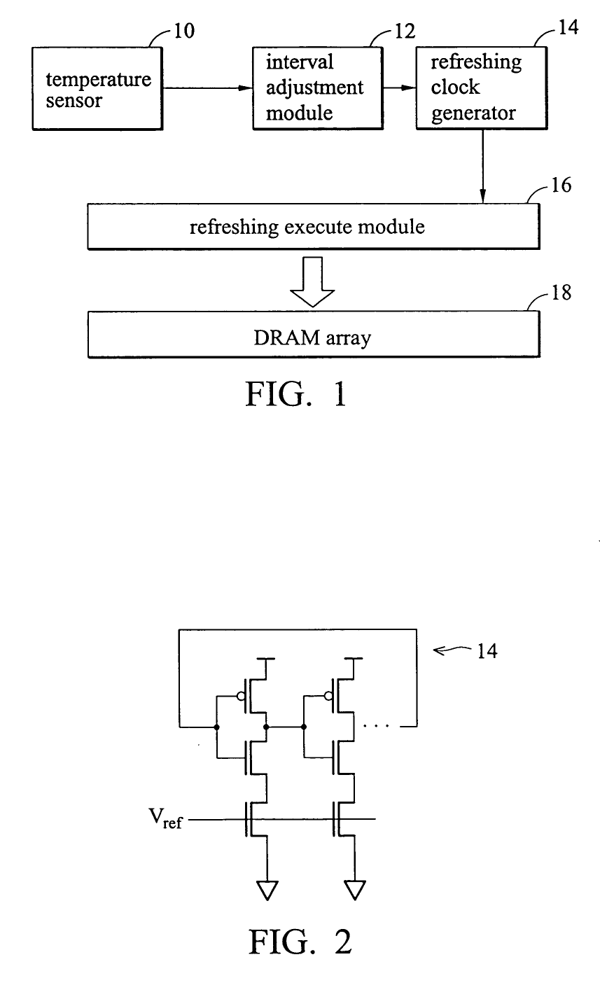

FIG. 1 is a block diagram illustrating the present invention. A temperature sensor 10 detects a working temperature for the DRAM, providing a corresponding temperature signal to a refresh interval adjustment module 12, which then sets a corresponding refresh interval accordingly, and directs clock generator 14 to finally generate a corresponding refresh timing clock. Refresh module 16, according to the refresh timing clock, executes a refresh on DRAM array 18.

The temperature sensor 10 is a conventional energy gap voltage reference source, generating a reference voltage (V_{ref}) as a temperature signal. In general, the energy gap voltage reference source takes a forward biased voltage of a diode as a reference value, and generates a corresponding voltage. The relationship between the voltage and temperature can differ by circuit design, according to which the V_{ref} establishes a positive correlationship with the temperature.

The refresh interval adjustment module 12 can be a basic RC delay circuit, with the RC time constant controlled by V_{ref}, as shown in FIG. 2, wherein a part of an oscillator acts as the refresh interval adjustment module in FIG. 1. In FIG. 2, the gate of NMOS is controlled by V_{ref}, which decreases with temperature, and which drives the equivalent resistance of a discharging path to increase. Accordingly, the frequency of the oscillator decreases, increasing the refresh interval equivalently.

The refresh interval and the working temperature do not necessary maintain linear relationship, such that a temperature range can correspond to a refresh interval, with another, higher, temperature range corresponding to anther lower temperature interval. Thus the relationship between temperature and working temperature can be preset by a built-in comparison table.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation to encompass all such modifications and similar arrangements.

1. A method of refreshing a DRAM chip, comprising:
detecting a working temperature for the DRAM;
setting a corresponding refresh interval according to the working temperature; and
generating a refresh timing clock with the corresponding refresh interval, and executing a refresh process for the DRAM.

2. The method of refreshing a DRAM chip in claim 1, wherein, when the working temperature is within a first temperature range, the corresponding refresh interval is determined as a first refresh interval, and when the working temperature is within a second temperature range, the corresponding refresh interval is determined as a second refresh interval.

3. The method of refreshing a DRAM chip in claim 2, wherein the corresponding refresh interval is determined according to a comparison table.

4. The method of refreshing a DRAM chip in claim 2, wherein the first temperature range is higher than the second temperature range and the first refresh interval is shorter than the second refresh interval.

5. The method of refreshing a DRAM chip in claim 1, wherein the working temperature is detected by an energy gap voltage reference source, to output a reference voltage.

6. The method of refreshing a DRAM chip in claim 5, wherein the reference voltage is used to control a frequency of an oscillator, thereby providing the corresponding refresh interval.

7. A DRAM refresh system, embedded in a DRAM chip, comprising:
a temperature sensor detecting a working temperature for the DRAM, to generate a corresponding temperature signal;
a refresh interval adjustment module deciding a corresponding refresh interval according to the temperature signal;
a clock generator generating a refresh timing clock with the corresponding refresh interval; and
a refresh module executing a refresh for the DRAM according to the refresh timing clock.

8. The DRAM refresh system of claim 7, wherein the temperature sensor is an energy gap voltage reference source.

9. The DRAM refresh system of claim 7, wherein the refresh interval adjustment module is an oscillator.
